(19) United States
(12) Patent Application Publication
(10) Pub. No.: US 2013/0009124 A1
(43) Pub. Date: Jan. 10, 2013

(54) RESISTIVE RAM HAVING THE FUNCTION OF DIODE RECTIFICATION

(76) Inventors: Ting-Chang CHANG, Kaohsiung City (TW); Yong-En SYU, Tainan City (TW); Fu-Yen JIAN, Kaohsiung City (TW); Ming-Jinn TSAI, Hsinchu City (TW)

(21) Appl. No.: 13/237,368

(22) Filed: Sep. 20, 2011

(30) Foreign Application Priority Data
Jul. 8, 2011 (TW) 100124192

(51) Int. Cl. H01L 45/00

(52) U.S. Cl. 257/4; 257/E45.003

(57) ABSTRACT

A type of resistance random access memory structure having the function of diode rectification includes a first electrode, a second electrode and a resistance conversion layer. The resistance conversion layer is disposed between the first electrode and the second electrode; and it includes a first oxidized insulating layer which is adjacently connected to the first electrode; a second oxidized insulating layer which is adjacently connected to the second electrode; as well as an energy barrier turning layer disposing between the first oxidized insulating layer and the second oxidized insulating layer. An energy barrier high can be adjusted and controlled to change the resistance by voltage between the energy barrier turning layer and the first oxidized insulating layer. A fixed energy barrier is formed between the second oxidized insulating layer and the energy barrier turning layer, so that the resistance random access memory element features the function of diode rectification.

### CROSS-REFERENCE TO RELATED APPLICATION

This application claims the benefit of Taiwan Patent Application No. 100124192, filed on Jul. 8, 2011, which is hereby incorporated by reference for all purposes as if fully set forth herein.

### BACKGROUND OF THE DISCLOSURE

1. Field of Disclosure

The present disclosure relates to a type of resistance random access memory and more particularly to a resistance random access memory featuring the characteristics of variable resistor and diode rectification by adjusting and controlling the energy barrier through voltage.

2. Related Art

Referring to FIG. 1A, it shows conventional resistance memory applied in cross-point memory array; FIG. 1B shows a 1T1R structure of conventional resistance memory; FIG. 1C shows a 1D1R structure of conventional resistance memory.

Generally, memory is often structured to form memory array. FIG. 1A depicts resistance memory applied in cross-point array structure. When a selected memory cell 11 is in off status, the targeted memory cell 11's actual status can be misjudged which is affected by an adjacent and the unselected memory cell 12's on status (the dotted lines as shown in FIG. 1A), so that resistance memory cannot be applied in reading memory cells alone.

Therefore, a resistor element 10 is often used with a transistor 13 to form a 1T1R structure as shown in FIG. 1B, or the resistor 10 is used with a diode 14 to form a 1D1R structure as shown in FIG. 1C. These types of structures (1T1R or 1D1R) are then integrated into the memory array.

### SUMMARY OF THE DISCLOSURE

The present disclosure of a type of resistance random access memory (RRAM) structure having the function of diode rectification includes a first electrode, a second electrode and a resistance conversion layer. The resistance conversion layer is disposed between the first electrode and the second electrode; and it includes a first oxidized insulating layer which is adjacently connected to the first electrode; a second oxidized insulating layer which is adjacently connected to the second electrode; as well as an energy barrier turning layer disposing between the first oxidized insulating layer and the second oxidized insulating layer. Energy barrier high can be adjusted and controlled to change the resistance by voltage between the energy barrier turning layer and the first oxidized insulating layer A fixed energy barrier is formed between the second oxidized insulating layer and the energy barrier turning layer, so that the resistance random access memory element features the function of diode rectification.

The present disclosure will become more fully understood by reference to the following detailed description thereof when read in conjunction with the attached drawings.

### BRIEF DESCRIPTION OF THE DRAWINGS

FIG. 1A is an illustration of conventional resistance memory applied in a cross-point memory array;

FIG. 1B is an illustration of a 1T1R structure of conventional resistance memory;

FIG. 1C is an illustration of a 1D1R structure of conventional resistance memory;

FIG. 2 is an illustration of a memory cell structure of the present disclosure of a resistance random access memory;

FIG. 3 is an illustration of a local conductive path formation of the present disclosure of a resistance random access memory;

FIG. 4 is an illustration of variable resistor characteristics of the present disclosure of a resistance random access memory;

FIG. 5 is an I-V graph of variable resistor characteristics of the present disclosure of a resistance random access memory;

FIG. 6 is an illustration of diode characteristics of the present disclosure of a resistance random access memory;

FIG. 7 is an I-V graph of diode characteristics of the present disclosure of a resistance random access memory;

FIG. 8 is an I-V graph of the present disclosure of a resistance random access memory; and

FIG. 9 is an illustration of the present disclosure of a resistance random access memory integrated into a memory array.

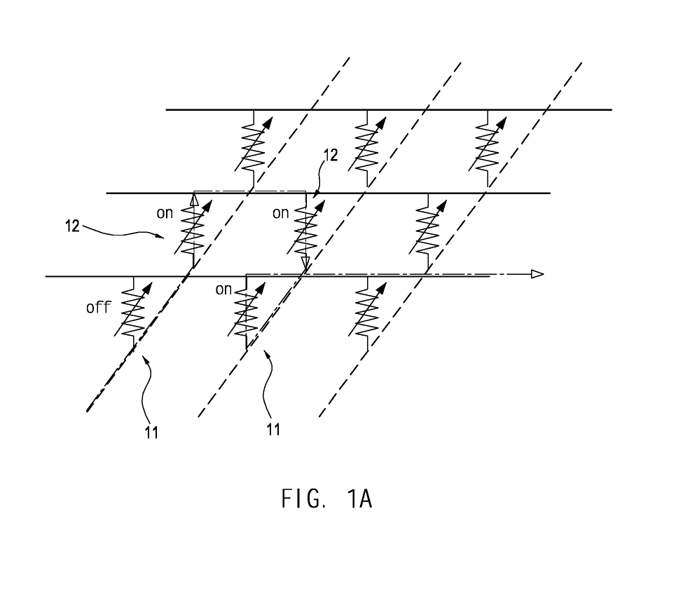

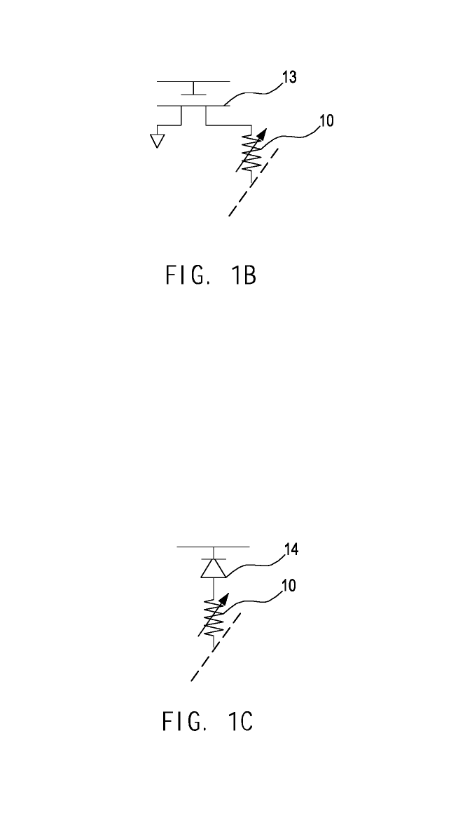

### DETAILED DESCRIPTION OF THE DISCLOSURE

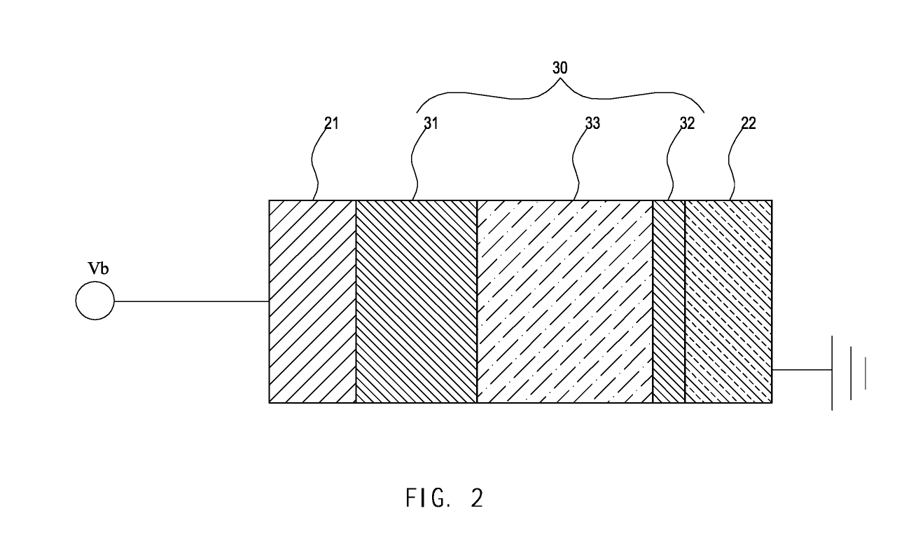

Referring to FIG. 2, it shows a memory cell structure of the present disclosure of a resistance random access memory. A memory cell structure of the resistance random access memory includes a first electrode 21, a resistance conversion layer 30 and a second electrode 22. The resistance conversion layer 30 is disposed between the first electrode 21 and the second electrode 22. The resistance conversion layer 30 includes a first oxidized insulating layer 31, an energy barrier turning layer 33 and a second oxidized insulating layer 32. The energy barrier turning layer 33 is disposed between the first oxidized insulating layer 31 and the second oxidized insulating layer 32. In this preferred embodiment, the first oxidized insulating layer 31 is adjacently connected to the first electrode 21; the second oxidized insulating layer 32 is adjacently connected to the second electrode 22.

Wherein, the first electrode 21 can be a type of conductor or semi-conductor including the conducting materials of platinum, gold, aluminum, titanium, tungsten, ruthenium, tantalum, titanium nitride or silicon. The second electrode 22 is made of silicon-based material (N⁺ Si) with arsenium ions, or is a type of conductor or semi-conductor including the conducting materials of platinum, gold, aluminum, titanium, tungsten, ruthenium, tantalum, titanium nitride or silicon.

Oxide materials of the first oxidized insulating layer 31 including oxides of silicon, hafnium, aluminum, zirconium, niobium, titanium, tantalum and lanthanum, for examples, oxides in stoichiometric ratio such as SiO₂, HfO₂, Al₂O₃, ZrO₂, NbO, TiO₂, NiO, Ta₂O₅ and La₂O₃, or other similar oxides, but not limited to the above-mentioned oxides. The second oxidized insulating layer 32 adopts the same oxide elements as used in the first oxidized insulating layer 31, or different oxide elements as required by designers.

The energy barrier turning layer 33 adopts a silicon nitride layer (a chemical compound of silicon and nitrogen) in stoichiometric ratio with energy gaps which can be increased by increasing the oxygen ratio. The silicon nitride layer also includes silicon, germanium, germanium-oxygen compound (GeN), or metallic oxides with excess metals. In this embodiment, silicon nitride (Si₃N₄) is used as an example but is not limited to it, as required otherwise by designers.

According to the structure of the resistance conversion layer 30, an energy barrier is formed between the energy barrier turning layer 33 and the first oxidized insulating layer 31; a fixed energy barrier is formed between the energy barrier turning layer 33 and the second oxidized insulating layer 32.

It should be noted that the energy barrier mentioned here refers to the barrier in electron transport, but not the energy barrier of the combination of molecules. Wherein, when a bias voltage (Vb) is applied across the first electrode 21 and the second electrode 22, the resistance conversion layer 30 will feature the characteristics of a variable resistor or diode depending on the voltage polarity. When the resistance conversion layer 30 shows the characteristics of a variable resistor; the afore-mentioned energy barrier high can be adjusted by the interaction of the energy barrier turning layer 33 and the first oxidized insulating layer 31; so that the resistance of the resistance random access memory can be adjusted. The activation of generating process for resistance random access memory, and the operating of variable resistor characteristics and diode characteristics are explained below.

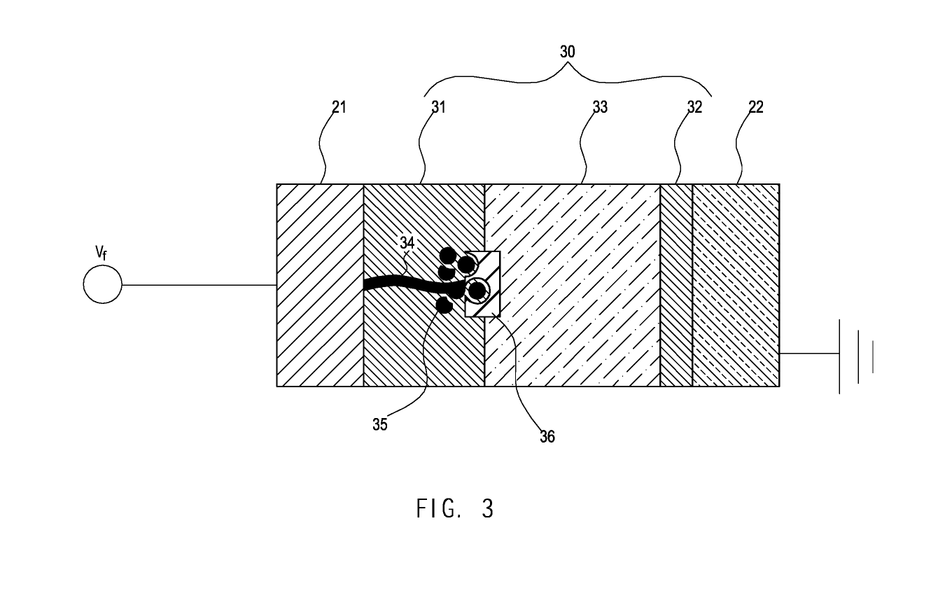

FIG. 3 depicts a local conductive path formation of the generating process of the present disclosure of a resistance random access memory.

A formation voltage (Vf) is applied across the first electrode 21 and the second electrode 22, the second electrode 22 is grounded and a voltage of negative 30 volts (−0V) is applied to the first electrode 21. This operation process causes the soft breakdown of the first oxidized insulating layer 31 and a local conductive path 34 is formed. Wherein, the bonds of oxygen ions (O⁻²) 35 of the first oxidized insulating layer 31 are broken and are able to interact with the elements (Si and N) of the energy barrier turning layer 33 to form a local energy barrier turning layer (SiONx) 36.

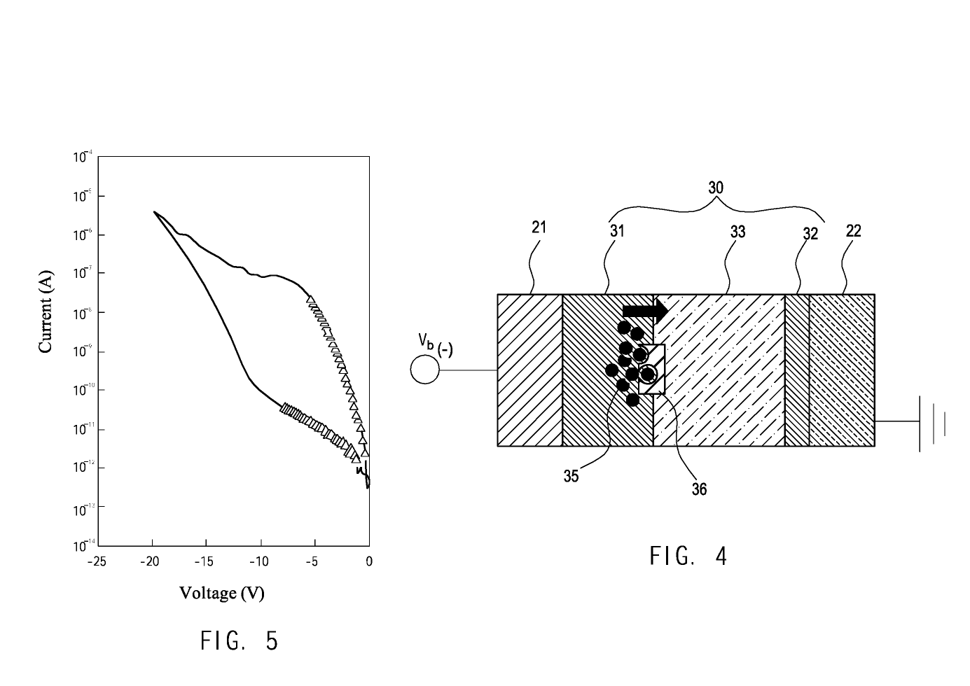

FIG. 4 shows the operation of the variable resistor characteristics of the present disclosure of a resistance random access memory. It will become more fully understood by reference to the following detailed descriptions thereof when read in conjunction with FIG. 3, and FIG. 5 which shows a graph of the variable resistor characteristics of the present disclosure of a resistance random access memory.

A negative bias voltage (Vb) is applied across the first electrode 21 and the second electrode 22. Under the assistance of suitable electric field conditions and the local conductive path 34, the oxygen ions 35 of the first oxidized insulating layer 31 interact and combine with the elements of the energy barrier turning layer 33 (formation of SiONx) in the local interface of the first oxidized insulating layer 31 and the energy barrier turning layer 33. In the partial energy barrier turning layer 36, the oxygen level in SiONx formed with Si₃N₄ can affect the energy barrier high. Thus the energy barrier high between the first oxidized insulating layer 31 and the energy barrier turning layer 33 would different after applying the voltage. But the energy barrier high (for the fixed energy barrier) between the second oxidized insulating layer 32 and the energy barrier turning layer 33 remains the same.

In other words, the energy barrier high is controlled by the interaction intensity of combination and detachment of oxygen ions of the first oxidized insulating layer 31 and the elements of the energy barrier turning layer 33. Yet, the interaction intensity of combination and detachment is controlled by the volts of either a positive or a negative voltage. Therefore, the resistance of the resistance random access memory can be adjusted by changing the energy barrier high, in order to be applied in data memory.

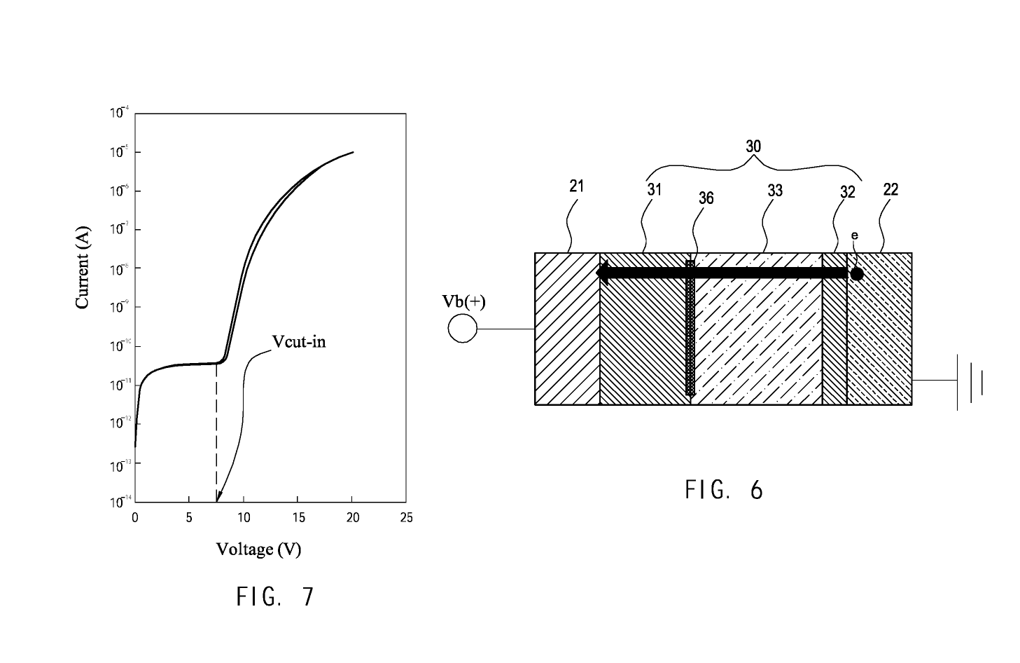

FIG. 6 shows the operation of the diode characteristics of the present disclosure of a resistance random access memory. It will become more fully understood by reference to the following detailed descriptions thereof when read in conjunction with FIG. 7 which shows a graph of the diode characteristics of the present disclosure of a resistance random access memory.

A positive bias voltage Vb is applied across the first electrode 21 and the second electrode 22. An electron flows sequentially from the second electrode 22, the second oxidized insulating layer 32, the energy barrier turning layer 33, the first oxidized insulating layer 31 and then to the first electrode 21.

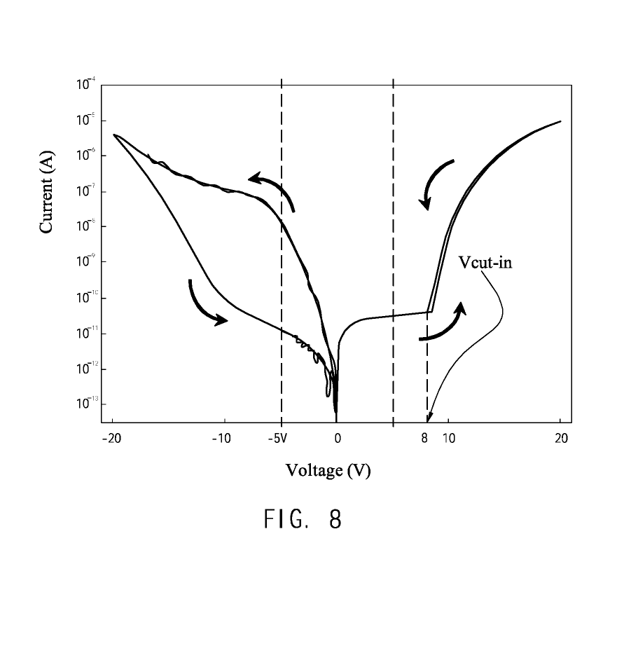

However, there are two problems related to energy for movement of the electron. Firstly, the energy barrier between the second oxidized insulating layer 32 and the second electrode 22. Secondly, the energy difference of conductive band between the energy barrier turning layer 33 and the second electrode 22. In other words, although the bias voltage Vb provides more energy for the electron e, the energy level of electron e must be equal to or higher than the afore-mentioned energy difference of conductive band, in order to have a chance to pass through the second oxidized insulating layer 32 and reaches the first electrode 21. In other words, the current in the resistance random access memory will be limited once the energy level of electron e is lower than the afore-mentioned energy difference of conductive band. This type of working mode is the mechanism of rectification. The bias voltage to enable electrons to possess more energy than the energy difference of conductive band is the cut-in voltage (shown as Vcut-in in FIGS. 7 and 8) to generate current. The both processes cause the resistance random access memory to show the characteristics of a diode.

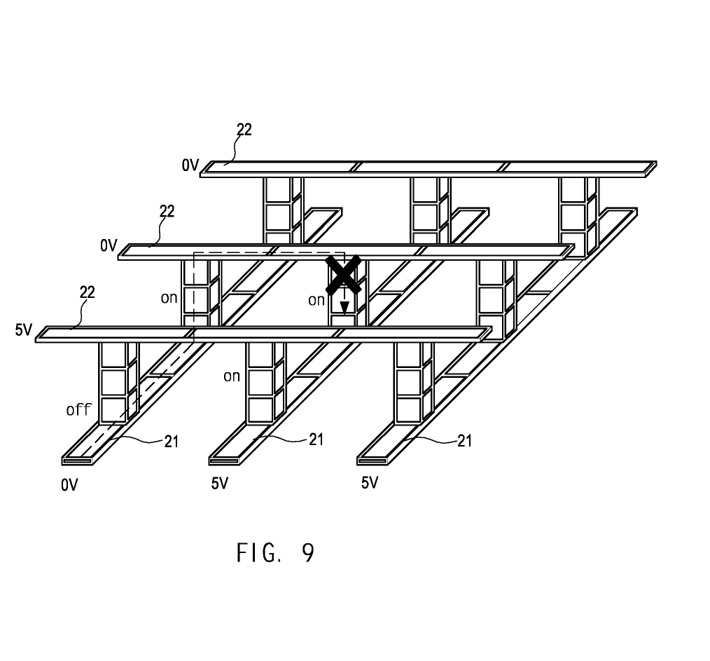

FIG. 8 shows an I-V graph of the present disclosure of a resistance random access memory. FIG. 9 shows the present disclosure of a resistance random access memory integrated into memory array. It will become more fully understood by reference to the following detailed descriptions thereof when read in conjunction with FIGS. 5 to 7.

FIG. 8 shows that the bias voltages for writing and erasing data are within the ranges of >10V and <−10V respectively, 0˜−5V for reading and 0V˜8V for rectification.

According to the ways of bias voltage supply as shown in FIG. 9, when a targeted memory cell 41 is in off status, and an unselected memory cell 42 which is adjacent to the targeted memory cell 41, is in on status, will cause misjudged electric current (dotted lines as shown in FIG. 9). It will be rectified by a certain unselected memory cell 42 which is in on status and shows the characteristics of diode, so as to eliminate the reverse current. Therefore, the reading of the real status of the selected memory cell 41 will not be affected.

Note that the specifications relating to the above embodiments should be construed as exemplary rather than as limitative of the present disclosure, with many variations and modifications being readily attainable by a person of average skill in the art without departing from the spirit or scope thereof as defined by the appended claims and their legal equivalents.

What is claimed is:

1. A resistance random access memory structure having the function of diode rectification includes:
a first electrode;
a second electrode and;
a resistance conversion layer disposed between said first electrode and said second electrode, said resistance conversion layer includes:
a first oxidized insulating layer connected adjacent to said first electrode;
a second oxidized insulating layer connected adjacent to said second electrode, and;
an energy barrier turning layer disposed between said first oxidized insulating layer and said second oxidized insulating layer, an energy barrier is formed between said energy barrier turning layer and said first oxidized insulating layer, a fixed energy barrier is formed between said energy barrier turning layer and said second oxidized insulating layer, wherein, when a bias voltage is applied across said first electrode and said second electrode, said resistance conversion layer shows variable resistor characteristics which said energy barrier high can be adjusted by interaction between said energy barrier turning layer and said first oxidized insulating layer, and diode characteristics which electric current can be adjusted by said fixed energy barrier.

2. The resistance random access memory structure having the function of diode rectification as claimed in claim 1, wherein when said bias voltage is either a negative or a positive voltage, said energy barrier high between said first oxidized insulating layer and said energy barrier turning layer is controlled and changed to show said variable resistor characteristics.

3. The resistance random access memory structure having the function of diode rectification as claimed in claim 2, wherein said energy barrier high is controlled by interaction of combination of oxygen ions of said first oxidized insulating layer and elements of said energy barrier turning layer, interaction intensity of said combination and detachment is controlled by the volts of said positive or said negative voltage.

4. The resistance random access memory structure having the function of diode rectification as claimed in claim 1, wherein when said bias voltage is a positive voltage, said fixed energy barrier between said second oxidized insulating layer and said energy barrier turning layer is used for adjusting electric current to show said diode characteristics.

5. The resistance random access memory structure having the function of diode rectification as claimed in claim 4, wherein when an electron's energy is higher than the energy difference of conductive band between said energy barrier turning layer and said second electrode, so that said electron can pass through said second oxidized insulating layer from said second electrode, and move from said resistance conversion layer to said first electrode.

6. The resistance random access memory structure having the function of diode rectification as claimed in claim 1, wherein said first electrode includes platinum (Pt), gold (Au), aluminum (Al), titanium (Ti), tungsten (W), ruthenium (Ru), tantalum (Ta), titanium nitride (TiN) or silicon (Si).

7. The resistance random access memory structure having the function of diode rectification as claimed in claim 1, wherein said second electrode is made of silicon-based material (N⁺ Si) with arsenium (As) ions, or includes platinum (Pt), gold (Au), aluminum (Al), titanium (Ti), tungsten (W), ruthenium (Ru), tantalum (Ta), titanium nitride (TiN) or silicon (Si).

8. The resistance random access memory structure having the function of diode rectification as claimed in claim 1, wherein said first oxidized insulating layer and said second oxidized insulating layer are layers of oxides in stoichiometric ratio.

9. The resistance random access memory structure having the function of diode rectification as claimed in claim 8, wherein said first oxidized insulating layer is made of compounds of oxides including silicon (Si), hafnium (Hf), aluminum (Al), zirconium (Zr), niobium (Nb), titanium (Ti), tantalum (Ta) and lanthanum (La).

10. The resistance random access memory structure having the function of diode rectification as claimed in claim 8, wherein said second oxidized insulating layer and said first oxidized insulating layer adopt oxides with the same elements.

11. The resistance random access memory structure having the function of diode rectification as claimed in claim 8, wherein said second oxidized insulating layer and said first oxidized insulating layer adopt oxides with different elements.

12. The resistance random access memory structure having the function of diode rectification as claimed in claim 1, wherein said energy barrier turning layer is a silicon nitride layer of stoichiometric ratio with energy gaps which can be increased by increasing the oxygen ratio, said silicon nitride layer also includes silicon (Si), germanium (Ge), germanium-oxygen compound (GeN), or metallic oxides with excess metals.

13. The resistance random access memory structure having the function of diode rectification as claimed in claim 1, wherein said energy barrier turning layer includes silicon nitride (Si₃N₄).
